(19) United States
(12) Patent Application Publication
(10) Pub. No.: US 2026/0114213 A1
(43) Pub. Date: Apr. 23, 2026

(54) SUBSTRATE PROCESSING MODULE AND SUBSTRATE PROCESSING METHOD

(71) Applicant: EBARA CORPORATION, Tokyo (JP)

(72) Inventors: SAKI MIYAGAWA, Tokyo (JP); KEIICHIRO NOMURA, Tokyo (JP); MITSURU MIYAZAKI, Tokyo (JP)

(73) Assignee: EBARA CORPORATION, Tokyo (JP)

(21) Appl. No.: 19/324,162

(22) Filed: Sep. 10, 2025

(30) Foreign Application Priority Data
Oct. 17, 2024 (JP) 2024-181492

(51) Int. Cl. H01L 21/67; B08B 3/02; B08B 13/00; B24B 37/04; F26B 19/00

(52) U.S. Cl. CPC H10P 72/0414; B08B 3/022; B08B 3/024; B08B 13/00; B24B 37/04; F26B 19/00

(57) ABSTRACT

A substrate processing module includes: a substrate holding part; a first nozzle for supplying a first fluid used in a first process; a second nozzle supplying a second fluid used in a second process; a first nozzle arm; a second nozzle arm, a first swing mechanism for swinging the first nozzle arm, a second swing mechanism for swinging the second nozzle arm; a carry-in port of a substrate; and a carry-out port of the substrate. The carry-in port and the carry-out port are arranged symmetrically with respect to a reference line. The reference line is a line that passes through the substrate holding surface and extends parallel to the substrate holding surface. A first swing shaft is arranged to be adjacent to the carry-in port, and a second swing shaft is arranged to be adjacent to the carry-out port.

### CROSS-REFERENCE TO RELATED APPLICATION

This application claims the priority benefit of Japan application serial no. 2024-181492, filed on Oct. 17, 2024. The entirety of the above-mentioned patent application is hereby incorporated by reference herein and made a part of this specification.

### BACKGROUND

### Technical Field

The invention relates to a substrate processing module and a substrate processing method, and particularly relates to a substrate processing module and a substrate processing method for performing substrate processing (for example, cleaning process, drying process) after polishing.

### Description of Related Art

In the manufacturing process of semiconductor devices, the surface of a wafer is polished to remove unnecessary material films. The polishing of the wafer surface is performed by bringing the wafer surface into sliding contact with a polishing pad while supplying a slurry onto the polishing pad. Such polishing using a polishing pad and slurry is referred to chemical mechanical polishing (CMP).

A CMP device includes a device having a polishing module that performs the chemical mechanical polishing (CMP), a cleaning module that cleans the wafer after polishing, and a drying module that dries the cleaned wafer. The wafer polished in the polishing module is transported to the cleaning module and the drying module by a transport device, and is cleaned and dried in the cleaning module and the drying module.

### PRIOR ART DOCUMENT(S)

### Patent Document(s)

[Patent Document 1] Japanese Patent Application Laid-open No. 2010-50436

Generally, in a CMP device, it is necessary to provide multiple polishing modules, multiple cleaning modules, and multiple drying modules within a limited space. Therefore, when the wafer diameter and the module quantity to be mounted increase, miniaturization of each module has been a challenge. Additionally, transporting wafers between modules may require time, and when one wafer is processed with multiple modules, the throughput may decrease.

Therefore, the invention provides a substrate processing module and a substrate processing method that can promptly perform substrate processing after polishing (for example, cleaning process, drying process) in a space-saving manner.

### SUMMARY

In an aspect, a substrate processing module that performs a first process and a second process after the first process on a substrate is provided. The substrate processing module includes: a substrate holding part, holding the substrate; a first nozzle, supplying a first fluid used in the first process to the substrate; a second nozzle, supplying a second fluid used in the second process to the substrate; supporting the first nozzle; a second nozzle arm, supporting the second nozzle; a first swing mechanism, swinging the first nozzle arm in a direction parallel to a substrate holding surface of the substrate holding part; a second swing mechanism, swinging the second nozzle arm in a direction parallel to the substrate holding surface; a carry-in port, provided to carry the substrate into the substrate processing module; and a carry-out port, provided to carry the substrate out of the substrate processing module. The carry-in port and the carry-out port are arranged symmetrically with respect to a reference line when viewed from top of the substrate processing module, and the reference line is a line that passes through the substrate holding surface when viewed from the top of the substrate processing module and extends parallel to the substrate holding surface. A first swing shaft of the first swing mechanism is arranged adjacent to the carry-in port. A second swing shaft of the second swing mechanism is arranged adjacent to the carry-out port.

In an aspect, a substrate processing method performing a first process and a second process after the first process on a substrate is provided. The substrate processing method includes: carrying the substrate into a substrate processing module through a carry-in port; holding the substrate by using a substrate holding part; swinging a first nozzle arm in a direction parallel to a substrate holding surface of the substrate holding part by using a first swing mechanism while supplying a first fluid from a first nozzle supported by the first nozzle arm to the substrate to perform the first process on the substrate; swinging a second nozzle arm in a direction parallel to the substrate holding surface by using a second swing mechanism while supplying a second fluid from a second nozzle supported by the second nozzle arm to the substrate to perform the second process on the substrate; and carrying out the substrate from the substrate processing module through a carry-out port. The carry-in port and the carry-out port are arranged symmetrically with respect to a reference line when viewed from top of the substrate processing module. The reference line is a line that passes through the substrate holding surface when viewed from the top of the substrate processing module and extends parallel to the substrate holding surface. A first swing shaft of the first swing mechanism is arranged adjacent to the carry-in port. A second swing shaft of the second swing mechanism is arranged adjacent to the carry-out port.

In an aspect, the first nozzle arm and the second nozzle arm are at a same height.

### BRIEF DESCRIPTION OF THE DRAWINGS

FIG. 1 is a plan view showing one embodiment of a substrate processing module.

FIG. 2 is a side view of the substrate processing module shown in FIG. 1.

FIG. 3 is a diagram showing positions of a first nozzle arm and a second nozzle arm when the substrate is carried into the substrate processing module.

FIG. 4 is a diagram showing positions of the first nozzle arm and the second nozzle arm when the first process is performed on the substrate.

FIG. 5 is a diagram showing a state in which the first nozzle arm is moved to a retreat position before the second process.

FIG. 6 is a diagram showing positions of the first nozzle arm and the second nozzle arm when the second process is performed on the substrate.

FIG. 7 is a diagram showing positions of the first nozzle arm and the second nozzle arm when the substrate is carried out from the substrate processing module.

FIG. 8 is a diagram showing a state in which the first nozzle arm is moved to a first home position after the substrate is carried out from the substrate processing module.

FIG. 9 is a plan view showing another embodiment of the substrate processing module.

FIG. 10 is a plan view showing still another embodiment of the substrate processing module.

### DESCRIPTION OF THE EMBODIMENTS

Generally, in a CMP device, it is necessary to provide multiple polishing modules, multiple cleaning modules, and multiple drying modules within a limited space. Therefore, when the wafer diameter and the module quantity to be mounted increase, miniaturization of each module has been a challenge. Additionally, transporting wafers between modules may require time, and when one wafer is processed with multiple modules, the throughput may decrease.

Therefore, the invention provides a substrate processing module and a substrate processing method that can promptly perform substrate processing after polishing (for example, cleaning process, drying process) in a space-saving manner.

In an aspect, a substrate processing module that performs a first process and a second process after the first process on a substrate is provided. The substrate processing module includes: a substrate holding part, holding the substrate; a first nozzle, supplying a first fluid used in the first process to the substrate; a second nozzle, supplying a second fluid used in the second process to the substrate; supporting the first nozzle; a second nozzle arm, supporting the second nozzle; a first swing mechanism, swinging the first nozzle arm in a direction parallel to a substrate holding surface of the substrate holding part; a second swing mechanism, swinging the second nozzle arm in a direction parallel to the substrate holding surface; a carry-in port, provided to carry the substrate into the substrate processing module; and a carry-out port, provided to carry the substrate out of the substrate processing module. The carry-in port and the carry-out port are arranged symmetrically with respect to a reference line when viewed from top of the substrate processing module, and the reference line is a line that passes through the substrate holding surface when viewed from the top of the substrate processing module and extends parallel to the substrate holding surface. A first swing shaft of the first swing mechanism is arranged adjacent to the carry-in port. A second swing shaft of the second swing mechanism is arranged adjacent to the carry-out port.

In an aspect, the first nozzle arm and the second nozzle arm are at a same height.

In an aspect, the first swing mechanism is configured to move the first nozzle arm to a first home position and a retreat position. The second swing mechanism is configured to move the second nozzle arm to a second home position. The first home position is a position in which the first nozzle is arranged on an outer side of the substrate holding part and which is not on a carry-in path of the substrate. The retreat position is a position in which the first nozzle is arranged on the outer side of the substrate holding part and the second nozzle arm is not in contact with the first nozzle arm during swinging of the second nozzle arm. The second home position is a position in which the second nozzle is arranged on the outer side of the substrate holding part and which is not on a carry-out path of the substrate. The second home position is a position farther from the substrate holding part than the first home position

In an aspect, the substrate processing module further includes an operation control part controlling operations of the first swing mechanism and the second swing mechanism. The operation control part is configured to: give a command to the first swing mechanism to swing the first nozzle arm, while supplying the first fluid from the first nozzle to the substrate, and perform the first process on the substrate, then give a command to the first swing mechanism to move the first nozzle arm to the retreat position, and then give a command to the second swing mechanism to swing the second nozzle arm while supplying the second fluid from the second nozzle to the substrate, and perform the second process on the substrate.

In an aspect, the operation control part is configured to, before the substrate is carried in through the carry-in port, give a command to the second swing mechanism to move the second nozzle arm to the second home position and give a command to the first swing mechanism to move the first nozzle arm to the first home position.

In an aspect, the operation control part is configured to give a command to the second swing mechanism to move the second nozzle arm to the second home position after the second process is performed on the substrate and before the substrate is carried out through the carry-out port.

In an aspect, the operation control part is configured to give a command to the first swing mechanism to move the first nozzle arm to the first home position after the substrate is carried out through the carry-out port.

In an aspect, the first process is a cleaning process and the second process is a drying process. The first nozzle is a cleaning nozzle supplying a cleaning fluid used in the cleaning process to the substrate. The second nozzle is a drying nozzle supplying a drying fluid used in the drying process to the substrate.

In an aspect, the first process is a primary cleaning process and the second process is a finishing cleaning process. The first nozzle is a cleaning nozzle for supplying a primary cleaning fluid used in the primary cleaning process to the substrate. The second nozzle is a cleaning nozzle for supplying a finishing cleaning fluid used in the finishing cleaning process to the substrate.

In an aspect, a substrate processing method performing a first process and a second process after the first process on a substrate is provided. The substrate processing method includes: carrying the substrate into a substrate processing module through a carry-in port; holding the substrate by using a substrate holding part; swinging a first nozzle arm in a direction parallel to a substrate holding surface of the substrate holding part by using a first swing mechanism while supplying a first fluid from a first nozzle supported by the first nozzle arm to the substrate to perform the first process on the substrate; swinging a second nozzle arm in a direction parallel to the substrate holding surface by using a second swing mechanism while supplying a second fluid from a second nozzle supported by the second nozzle arm to the substrate to perform the second process on the substrate; and carrying out the substrate from the substrate processing module through a carry-out port. The carry-in port and the carry-out port are arranged symmetrically with respect to a reference line when viewed from top of the substrate processing module. The reference line is a line that passes through the substrate holding surface when viewed from the top of the substrate processing module and extends parallel to the substrate holding surface. A first swing shaft of the first swing mechanism is arranged adjacent to the carry-in port. A second swing shaft of the second swing mechanism is arranged adjacent to the carry-out port.

In an aspect, the first nozzle arm and the second nozzle arm are at a same height.

In an aspect, the substrate processing method further includes moving the first nozzle arm to a retreat position by using the first swing mechanism after the first process is performed on the substrate and before the second process is performed on the substrate. The retreat position is a position in which the first nozzle is arranged on an outer side of the substrate holding part and the second nozzle arm is not in contact with the first nozzle arm during swinging of the second nozzle arm.

In an aspect, the substrate processing method further includes moving the second nozzle arm to a second home position by using the second swing mechanism and moving the first nozzle arm to a first home position by using the first swing mechanism before the substrate is carried into the substrate processing module through the carry-in port. The first home position is a position in which the first nozzle is arranged on the outer side of the substrate holding part and which is not on a carry-in path of the substrate. The second home position is a position in which the second nozzle is arranged on the outer side of the substrate holding part and which is not on a carry-out path of the substrate. The second home position is a position farther from the substrate holding part than the first home position.

In an aspect, the substrate processing method further includes moving the second nozzle arm to a second home position by using the second swing mechanism after the second process is performed on the substrate and before the substrate is carried out from the substrate processing module through the carry-out port. The second home position is a position in which the second nozzle is arranged on the outer side of the substrate holding part and which is not on a carry-out path of the substrate.

In an aspect, the substrate processing method further includes moving the first nozzle arm to a first home position by using the first swing mechanism after the substrate is carried out from the substrate processing module through the carry-out port. The first home position is a position in which the first nozzle is arranged on the outer side of the substrate holding part and which is not on a carry-in path of the substrate.

In an aspect, the first process is a cleaning process, and the second process is a drying process, the first nozzle is a cleaning nozzle for supplying a cleaning fluid used in the cleaning process to the substrate. The second nozzle is a drying nozzle for supplying a drying fluid used in the drying process to the substrate.

In an aspect, the first process is a primary cleaning process and the second process is a finishing cleaning process. The first nozzle is a cleaning nozzle for supplying a primary cleaning fluid used in the primary cleaning process to the substrate. The second nozzle is a cleaning nozzle for supplying a finishing cleaning fluid used in the finishing cleaning process to the substrate.

Since the substrate processing module includes a first nozzle for performing a first process and a second nozzle for performing a second process, the first process and the second process can be continuously performed on the substrate within one substrate processing module. As a result, space saving of the substrate processing module and improvement of throughput can be achieved.

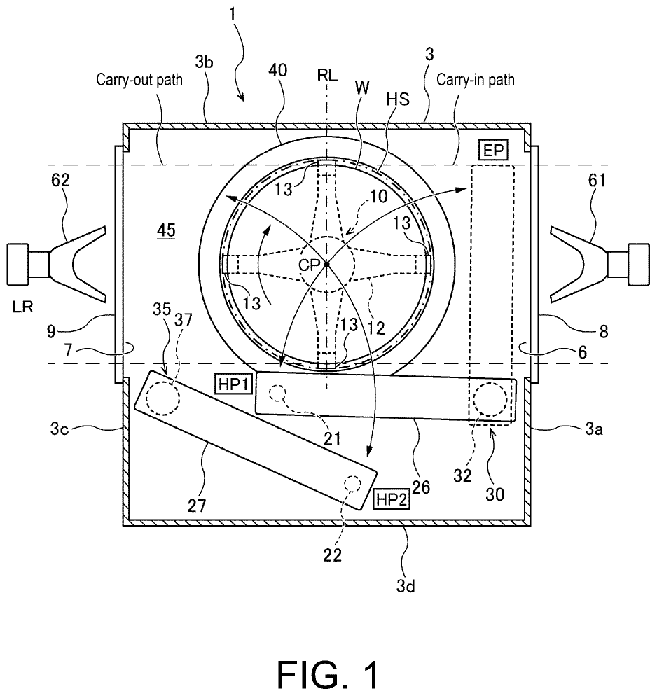

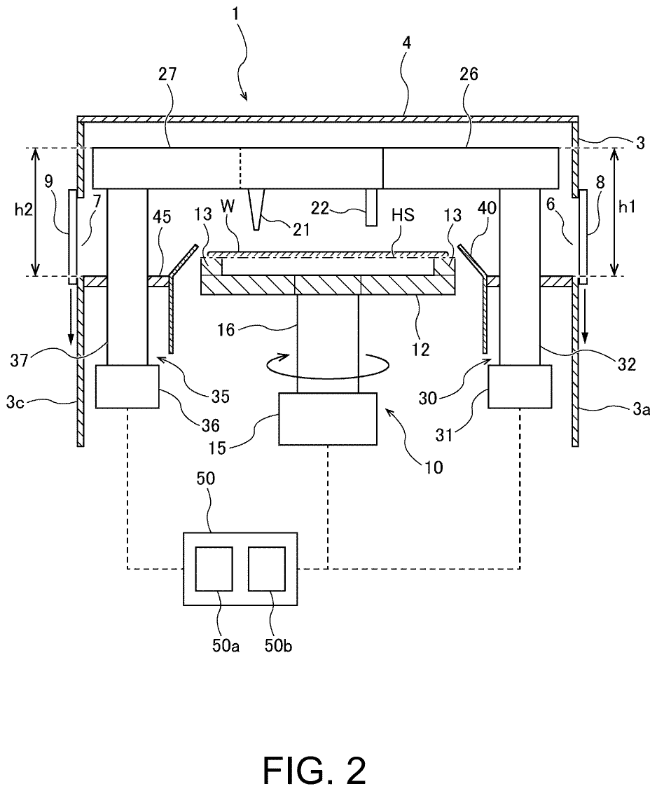

Hereinafter, embodiments of the invention will be described with reference to the drawings. FIG. 1 is a plan view showing one embodiment of a substrate processing module 1, and FIG. 2 is a side view of the substrate processing module 1 shown in FIG. 1. The substrate processing module 1 is a processing device for performing a first process on a substrate W and a second process after the first process. Specific examples of the substrate W include a wafer, a circular substrate, a square substrate, a panel, and the like used for a semiconductor device. In the embodiments described below, a circular wafer is used as the substrate W.

In the embodiment, the first process is a cleaning process performed on the substrate W after polishing (CMP process) has been performed in a polishing module not shown herein, and the second process is a drying process performed on the substrate W after cleaning.

The substrate processing module 1 includes a substrate holding part 10 that holds the substrate W, a first nozzle 21 that supplies a first fluid used in the first process to the substrate W, a second nozzle 22 that supplies a second fluid used in the second process to the substrate W, a first nozzle arm 26 that supports the first nozzle 21, a second nozzle arm 27 that supports the second nozzle 22, a first swing mechanism 30 that swings the first nozzle arm 26, and a second swing mechanism 35 that swings the second nozzle arm 27.

The substrate holding part 10 includes a holding wheel 12 that holds the substrate W, a rotation shaft 16 fixed to a lower part of the holding wheel 12, and a substrate rotation mechanism 15 that rotates the holding wheel 12. The holding wheel 12 has multiple (four in the present embodiment) holding chucks 13 that hold a peripheral part of the substrate W, and the substrate W is held on upper surfaces of the holding chucks 13. The substrate rotation mechanism 15 includes an electric motor, etc., and is connected to the holding wheel 12 via the rotation shaft 16. The substrate rotation mechanism 15 is configured to rotate the holding wheel 12 and the substrate W around the rotation shaft 16 in a direction indicated by arrows in FIG. 2. However, the configuration of the substrate holding part 10 is not limited to the embodiment, and the substrate holding part 10 may have other configurations as long as the substrate holding part 10 can hold and rotate the substrate W.

In the specification, a circular virtual plane that includes upper surfaces of the holding chucks 13 of the holding wheel 12 on which the substrate W is held and has the same diameter as the holding wheel 12 is referred to as a substrate holding surface HS of the substrate holding part 10. The substrate holding surface HS is parallel to a surface of the substrate W, and a center point CP of the substrate holding surface HS coincides with an axis of the substrate W.

The first nozzle 21 of the embodiment is a cleaning nozzle that supplies a cleaning fluid as a first fluid used in a cleaning process as the first process to the substrate W. The first nozzle 21 is configured to spray the cleaning fluid toward a surface of the substrate W that is held and rotated by the substrate holding part 10. Examples of the cleaning fluid include liquids such as chemical solutions and pure water, and a two-fluid jet formed by a mixed fluid of liquid (for example, chemical solutions, pure water) and gas.

The second nozzle 22 of the embodiment is a drying nozzle that supplies a drying fluid as a second fluid used in a drying process as the second process to the substrate W. The second nozzle 22 is configured to spray a drying fluid toward a surface of the substrate W that is held and rotated by the substrate holding part 10. Examples of the drying fluid include isopropyl alcohol (IPA) vapor (a mixture of IPA and inert gas such as N₂ gas), liquid (for example, IPA), gas (for example, N₂ gas), and the like. In one embodiment, the second nozzle 22 may be multiple nozzles, for example, configured to supply IPA vapor from one nozzle and supply pure water from the other nozzle.

The first swing mechanism 30 includes a first shaft rotation mechanism 31 and a first swing shaft 32. An end of the first nozzle arm 26 is connected to the first nozzle 21, and the other end of the first nozzle arm 26 is connected to the first swing shaft 32. The first swing shaft 32 is connected to the first shaft rotation mechanism 31 that rotates the first swing shaft 32. When the first shaft rotation mechanism 31 rotates the first swing shaft 32, the first nozzle arm 26 swings around the first swing shaft 32 in a direction parallel to the substrate holding surface HS. In this manner, the first swing mechanism 30 swings the first nozzle arm 26 around the first swing shaft 32 in a direction parallel to the substrate holding surface HS of the substrate holding part 10. The first nozzle 21 supported by the first nozzle arm 26 moves in the radial direction of the substrate holding surface HS according to swinging of the first nozzle arm 26.

The second swing mechanism 35 includes a second shaft rotation mechanism 36 and a second swing shaft 37. One end of the second nozzle arm 27 is connected to the second nozzle 22, and the other end of the second nozzle arm 27 is connected to the second swing shaft 37. The second swing shaft 37 is connected to the second shaft rotation mechanism 36 that rotates the second swing shaft 37. When the second shaft rotation mechanism 36 rotates the second swing shaft 37, the second nozzle arm 27 swings around the second swing shaft 37 in a direction parallel to the substrate holding surface HS. In this manner, the second swing mechanism 35 swings the second nozzle arm 27 around the second swing shaft 37 in a direction parallel to the substrate holding surface HS of the substrate holding part 10. The second nozzle 22 supported by the second nozzle arm 27 moves in a radial direction of the substrate holding surface HS according to swinging of the second nozzle arm 27.

The substrate processing module 1 includes a liquid splash prevention cup 40 having a shape that surrounds the substrate holding part 10. An upper portion of the liquid splash prevention cup 40 positioned on the outer side of the holding chuck 13 of the substrate holding part 10 has a truncated cone shape and is inclined inward toward an upper direction. The liquid splash prevention cup 40 can receive the first fluid and the second fluid scattered from the substrate W by a centrifugal force, and prevent the first fluid and the second fluid from scattering around the substrate W.

The substrate holding part 10, the first nozzle 21, the second nozzle 22, the first nozzle arm 26, the second nozzle arm 27, the first swing mechanism 30, the second swing mechanism 35, and the liquid splash prevention cup 40 are arranged within the substrate processing module 1 partitioned by a partition wall 3 and a ceiling 4. The substrate processing module 1 is isolated from the outside by the partition wall 3 and the ceiling 4. In the embodiment, as shown in FIG. 1, the partition wall 3 has a rectangular shape when the substrate processing module 1 is viewed from above. The partition wall 3 has four sidewalls 3a, 3b, 3c, 3d. The sidewall 3a and the sidewall 3c are parallel and face each other, and the sidewall 3b and the sidewall 3d are parallel and face each other. The sidewall 3a and the sidewall 3c are adjacent to the sidewall 3b and the sidewall 3d.

The partition wall 3 is arranged to surround a baseplate 45. The baseplate 45 partitions a space from an outer surface of the liquid splash prevention cup 40 to the partition wall 3 in an upper-lower direction. As shown in FIG. 2, the first swing shaft 32 of the first swing mechanism 30 and the second swing shaft 37 of the second swing mechanism 35 penetrate and extend through the baseplate 45.

The substrate processing module 1 includes a carry-in port 6 for carrying the substrate W into the substrate processing module 1, a carry-out port 7 for carrying the substrate W out from the substrate processing module 1, a first shutter 8 for opening and closing the carry-in port 6, and a second shutter 9 for opening and closing the carry-out port 7. The carry-in port 6 is formed in the sidewall 3a of the partition wall 3, and the carry-out port 7 is formed in the sidewall 3c of the partition wall 3. In the embodiment, the carry-in port 6 and the carry-out port 7 are arranged at positions facing each other on both sides of the substrate holding part 10.

The carry-in port 6 and the carry-out port 7 are arranged symmetrically with respect to a reference line RL when viewed from the top of the substrate processing module 1. The reference line RL is a virtual line that passes through the substrate holding surface HS of the substrate holding part 10 and extends parallel to the substrate holding surface HS when viewed from the top of the substrate processing module 1. In the embodiment, the reference line RL extends to pass through a center point CP of the substrate holding surface HS. In an embodiment, the reference line RL may not pass through the center point CP of the substrate holding surface HS, and may extend obliquely to pass through a corner part of the sidewall 3a and the sidewall 3b when viewed from the top of the substrate processing module 1, for example.

The first shutter 8 is attached to close the carry-in port 6 provided on the sidewall 3a. When the first shutter 8 is lowered, the carry-in port 6 is opened. The second shutter 9 is attached to close the carry-out port 7 provided on the sidewall 3c. When the second shutter 9 is lowered, the carry-out port 7 is opened. During the first process and the second process of the substrate W in the substrate processing module 1, the carry-in port 6 is closed by the first shutter 8, and the carry-out port 7 is closed by the second shutter 9.

The substrate W to be processed in the substrate processing module 1 is carried into the substrate processing module 1 through the carry-in port 6 by a first transport device 61. The substrate W is placed on the substrate holding part 10 by the first transport device 61 and held by the holding chuck 13 of the substrate holding part 10. When the first transport device 61 with which the substrate W is placed on the substrate holding part 10 exits from the substrate processing module 1, the first shutter 8 is raised and the carry-in port 6 is closed. When the processing of the substrate W ends, the second shutter 9 is lowered and the carry-out port 7 is opened. The substrate W processed in the substrate processing module 1 is carried out from the substrate processing module 1 through the carry-out port 7 by a second transport device 62. When the second transport device 62 holding the substrate W retreats from the substrate processing module 1, the second shutter 9 is raised and the carry-out port 7 is closed.

In the substrate processing module 1 of the embodiment, the carry-in port 6 for carrying in the substrate W before the first process and the second process and the carry-out port 7 for carrying out the substrate W after the first process and the second process are separately provided. Also, the first transport device 61 that transports the substrate W before the first process and the second process and the second transport device 62 that transports the substrate W after the first process and the second process are different transport devices. In this manner, by distinguishing the carry-in port, the carry-out port, and the transport devices used for the substrate W before and after processing, foreign matters can be prevented from being attached to the substrate W after processing, and the substrate W after processing can be maintained in a clean state.

As shown in FIG. 2, the substrate processing module 1 includes an operation control part 50 that controls the operations of the substrate holding part 10, the first swing mechanism 30, and the second swing mechanism 35. The operation control part 50 is formed by at least one computer. The operation control part 50 includes a memory device 50a in which programs are stored and an arithmetic device 50b that executes calculations according to the commands included in the programs. The memory device 50a includes a main memory device such as random access memory (RAM) and an auxiliary memory device such as a hard disk drive (HDD) or solid state drive (SSD). Examples of the arithmetic device 50b include a central processing unit (CPU) and a graphics processing unit (GPU). However, the specific configuration of the operation control part 50 is not limited to the examples.

As shown in FIG. 2, the first nozzle arm 26 and the second nozzle arm 27 have the same height. In the embodiment, a height h1 from the upper surface of the baseplate 45 to the upper end of the first nozzle arm 26 and a height h2 from the upper surface of the baseplate 45 to the upper end of the second nozzle arm 27 are the same. However, “having the same height” includes that a portion of the first nozzle arm 26 and a portion of the second nozzle arm 27 are at the same height. The first nozzle arm 26 and the second nozzle arm 27 having the same height may contact each other according to the mutual positional relationship.

It may also be considered to provide a mechanism for adjusting the heights of the first nozzle arm 26 and the second nozzle arm 27 to avoid contact between the first nozzle arm 26 and the second nozzle arm 27. However, adjusting the heights of the first nozzle arm 26 and the second nozzle arm 27 by a height adjustment mechanism is not preferable from the viewpoints that the height from the baseplate 45 to the ceiling 4 is limited, and the cost and installation space of the height adjustment mechanism.

Also, depending on the position of the first nozzle arm 26, the substrate W may contact the first nozzle arm 26 when the substrate W is carried in by the first transport device 61. Similarly, depending on the position of the second nozzle arm 27, the substrate W may contact the second nozzle arm 27 when the substrate W is carried out by the second transport device 62.

Therefore, in the embodiment, the first nozzle arm 26 and the second nozzle arm 27 are arranged so that the first nozzle arm 26 and the second nozzle arm 27 do not contact each other during the first process and the second process on the substrate W. Also, the first nozzle arm 26 and the second nozzle arm 27 are arranged so that the substrate W does not contact the first nozzle arm 26 and the second nozzle arm 27 when the substrate W is carried in and carried out.

The first swing shaft 32 of the first swing mechanism 30 is arranged adjacent to the carry-in port 6, and the second swing shaft 37 of the second swing mechanism 35 is arranged adjacent to the carry-out port 7. The first swing mechanism 30 is configured to move the first nozzle arm 26 to a first home position HP1 and a retreat position EP. The second swing mechanism 35 is configured to move the second nozzle arm 27 to the second home position HP2.

As described below, the first home position HP1 is the position of the first nozzle arm 26 when the substrate W is carried into the substrate processing module 1, the second home position HP2 is the position of the second nozzle arm 27 when the substrate W is carried into the substrate processing module 1, when the substrate W receives the first process by the first nozzle 21, and when the substrate W is carried out from the substrate processing module 1, and the retreat position EP is the position of the first nozzle arm 26 when the substrate W receives the second process by the second nozzle 22 and when the substrate W is carried out from the substrate processing module 1.

As shown in FIG. 1, the first home position HP1 is a position where the first nozzle 21 is arranged on the outer side of the substrate holding part 10, and not on the carry-in path of the substrate W indicated by the broken line in FIG. 1. That is, the first home position HP1 is a position where the first nozzle arm 26 is arranged on the outer side of the carry-in path of the substrate W. The carry-in path of the substrate W is a region including a trajectory along which the substrate W and the first transport device 61 move when the substrate W is carried in by the first transport device 61. The retreat position EP is a position where the first nozzle 21 is arranged on the outer side of the substrate holding part 10, and the second nozzle arm 27 does not contact the first nozzle arm 26 during swinging of the second nozzle arm 27. The first nozzle arm 26 at the retreat position EP is located between the carry-in port 6 and the substrate holding part 10.

The second home position HP2 is a position where the second nozzle 22 is arranged on the outer side of the substrate holding part 10, and not on the carry-out path of the substrate W indicated by the broken line in FIG. 1. That is, the second home position HP2 is a position where the second nozzle arm 27 is arranged outside the carry-out path of the substrate W. The carry-out path of the substrate W is a region including a trajectory along which the substrate W and the second transport device 62 move when the substrate W is carried out by the second transport device 62. The second home position HP2 is a position farther from the substrate holding part 10 than the first home position H1. That is, the first nozzle arm 26 at the first home position H1 is located between the second nozzle arm 27 at the second home position HP2 and the substrate holding part 10. In the embodiment, the carry-in path and the carry-out path of the substrate W extend perpendicularly to the reference line RL when viewed from the top of the substrate processing module 1.

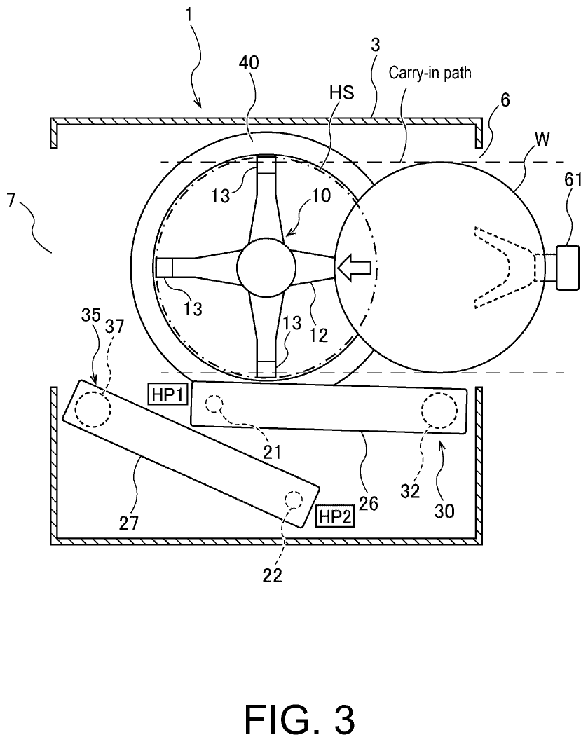

Hereinafter, with reference to FIG. 3 to FIG. 8, the operation of movement of the first nozzle arm 26 by the first swing mechanism 30 and the operation of movement of the second nozzle arm 27 by the second swing mechanism 35 when the substrate W is carried in, during the first process of the substrate W, during the second process, and when the substrate W is carried out will be described. In FIG. 3 to FIG. 8, the illustration of the first shutter 8 and the second shutter 9 is omitted.

FIG. 3 is a diagram showing the positions of the first nozzle arm 26 and the second nozzle arm 27 when the substrate W is carried into the substrate processing module 1. The operation control part 50 gives a command to the second swing mechanism 35 to move the second nozzle arm 27 to the second home position HP2 and gives a command to the first swing mechanism 30 to move the first nozzle arm 26 to the first home position HP1 before the substrate W is carried in through the carry-in port 6. When the second nozzle arm 27 is already positioned at the second home position HP2 and the first nozzle arm 26 is positioned at the first home position HP1, the operation is unnecessary.

In a state where the second nozzle arm 27 is positioned at the second home position HP2 and the first nozzle arm 26 is positioned at the first home position HP1, the substrate W is carried into the substrate processing module 1 by the first transport device 61. During carry-in of the substrate W, the first nozzle arm 26 is positioned at the first home position HP1 not on the carry-in path of the substrate W (separated from the carry-in path of the substrate W), so the substrate W does not contact the first nozzle arm 26. Similarly, during carry-in of the substrate W, the second nozzle arm 27 is positioned at the second home position HP2 not on the carry-in path of the substrate W (separated from the carry-in path of the substrate W), so the substrate W does not contact the second nozzle arm 27. The substrate W is transported to the substrate holding part 10 by the first transport device 61 and is held by the holding chuck 13 of the substrate holding part 10.

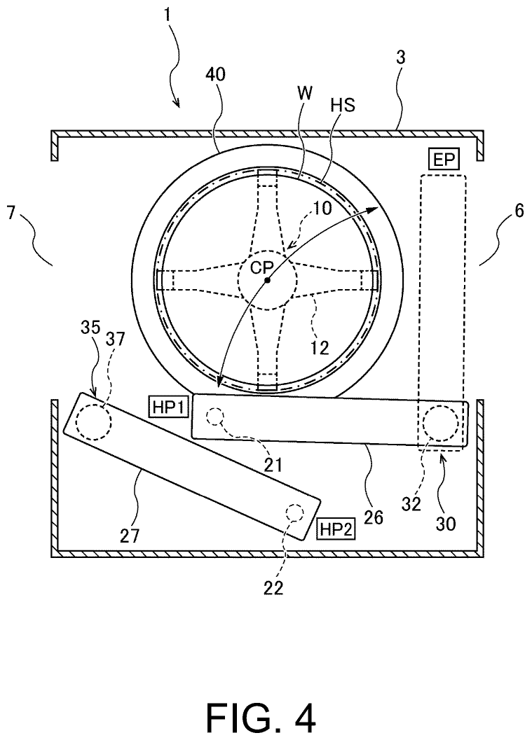

FIG. 4 is a diagram showing positions of the first nozzle arm 26 and the second nozzle arm 27 when the first process is performed on the substrate W. In the substrate processing module 1, the first process is performed on the substrate W initially. In the embodiment, the first process is a cleaning process performed on the substrate W after polishing (CMP process) is performed in a polishing module not shown. The operation control part 50 gives a command to the substrate rotation mechanism 15 of the substrate holding part 10 to rotate the substrate W. Thereafter, the operation control part 50 gives a command to the first swing mechanism 30 to swing the first nozzle arm 26 while supplying the first fluid (in the embodiment, cleaning fluid) from the first nozzle 21 to the substrate W to perform the first process (in the embodiment, cleaning process) on the substrate W.

During the first process of the substrate W, the first swing mechanism 30 swings the first nozzle arm 26 in a direction parallel to the substrate holding surface HS of the substrate holding part 10 around the first swing shaft 32. More specifically, the first swing mechanism 30 swings the first nozzle arm 26 between a swing start position and a swing end position so that the first nozzle 21 passes through the center point CP (axis of the substrate W) of the substrate holding surface HS. During supply of the first fluid to the substrate W, the first swing mechanism 30 may cause the first nozzle arm 26 to reciprocate once or multiple times between the swing start position and the swing end position, or may move from the swing start position to the swing end position without reciprocating.

In the embodiment, the swing start position of the first nozzle arm 26 is the first home position HP1, and the swing end position is the retreat position EP. However, the swing start position and swing end position of the first nozzle arm 26 are not particularly limited as long as the positions are positions where the first fluid can be supplied from the first nozzle 21 to the entire surface of the substrate W. For example, the swing end position of the first nozzle arm 26 may be a position closer to the substrate holding part 10 than the retreat position EP.

During the first process of the substrate W, the second nozzle arm 27 remains stationary at the second home position HP2, which is a position farther from the substrate holding part 10 than the first home position HP1, so the first nozzle arm 26 does not contact the second nozzle arm 27 even when the first nozzle arm 26 swings. The second home position HP2 is at a position farther from the substrate holding part 10 than the swing start position of the first nozzle arm 26.

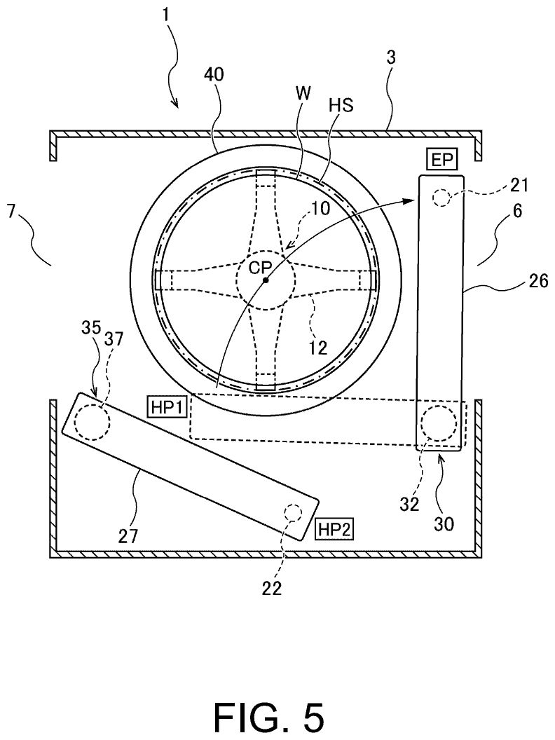

FIG. 5 is a diagram showing how the first nozzle arm 26 is moved to the retreat position EP before the second process. In the substrate processing module 1, the second process is performed on the substrate W after the first process is performed on the substrate W. The operation control part 50 gives a command to the first swing mechanism 30 to move the first nozzle arm 26 to the retreat position EP after the first process and before the second process. When the first process of the substrate W is completed when the first nozzle arm 26 is positioned at the retreat position EP, or when the first nozzle arm 26 is already positioned at the retreat position EP, the operation is unnecessary. The retreat position EP is a position where the first nozzle 21 is located on the outer side of the substrate holding part 10 and the second nozzle arm 27 does not contact the first nozzle arm 26 during swinging of the second nozzle arm 27. The retreat position EP is a position facing the carry-in port 6 and is within the carry-in path of the substrate W.

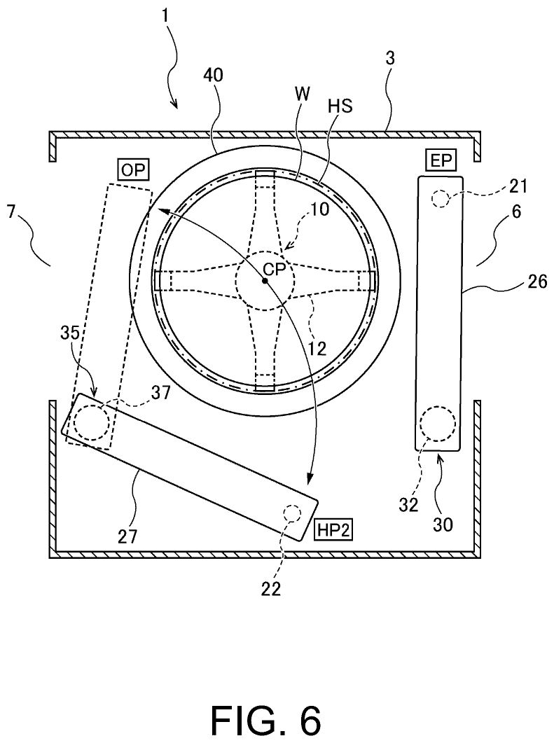

FIG. 6 is a diagram showing the positions of the first nozzle arm 26 and the second nozzle arm 27 when the second process is performed on the substrate W. In the embodiment, the second process is a drying process performed on the substrate W after the first process (in the embodiment, the cleaning process). The operation control part 50 gives a command to the second swing mechanism 35 to swing the second nozzle arm 27 while supplying the second fluid (in the embodiment, the drying fluid) from the second nozzle 22 to the rotating substrate W to perform the second process (in the embodiment, the drying process) on the substrate W.

During the second process of the substrate W, the second swing mechanism 35 swings the second nozzle arm 27 in a direction parallel to the substrate holding surface HS of the substrate holding part 10 around the second swing shaft 37. More specifically, the second swing mechanism 35 swings the second nozzle arm 27 between the swing start position and the swing end position so that the second nozzle 22 passes through the center point CP of the substrate holding surface HS (the axis of the substrate W). During the supply of the second fluid to the substrate W, the second swing mechanism 35 may reciprocate the second nozzle arm 27 between the swing start position and the swing end position once or multiple times, or may move the second nozzle arm 27 from the swing start position to the swing end position without reciprocating.

In the embodiment, the swing start position of the second nozzle arm 27 is the second home position H2, and the swing end position (indicated by a reference sign OP in FIG. 6) is a position facing the carry-out port 7 and is within the carry-out path of the substrate W. However, the swing start position and the swing end position of the second nozzle arm 27 are not particularly limited as long as the positions are positions where the second fluid can be supplied from the second nozzle 22 to the entire surface of the substrate W. For example, the swing start position of the second nozzle arm 27 may be a position closer to the substrate holding part 10 than the second home position H2.

During the second process of the substrate W, the first nozzle arm 26 is stationary at the retreat position EP, so the second nozzle arm 27 does not contact the first nozzle arm 26 even when the second nozzle arm 27 swings.

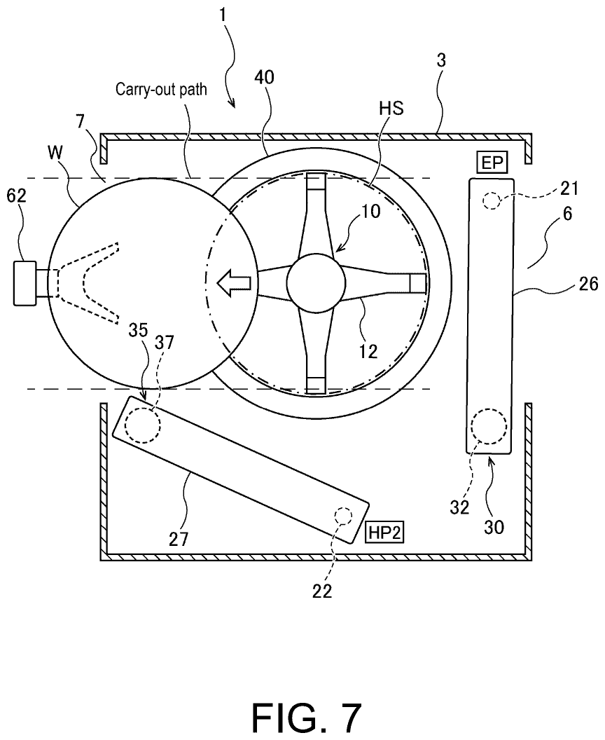

FIG. 7 is a diagram showing the positions of the first nozzle arm 26 and the second nozzle arm 27 when the substrate W is carried out from the substrate processing module 1. The operation control part 50 gives a command to the second swing mechanism 35 to move the second nozzle arm 27 to the second home position HP2 after the second process is performed on the substrate W and before the substrate W is carried out through the carry-out port 7. While the second nozzle arm 27 is moving to the second home position HP2, the first nozzle arm 26 is at the retreat position EP. Thereafter, the substrate W is carried out from the substrate processing module 1 by the second transport device 62.

When the substrate W is carried out, the second nozzle arm 27 is positioned at the second home position HP2 not on the carry-out path of the substrate W (separated from the carry-out path of the substrate W), so the substrate W does not contact the second nozzle arm 27. Similarly, when the substrate W is carried in, the first nozzle arm 26 is positioned at the retreat position EP not on the carry-out path of the substrate W (separated from the carry-out path of the substrate W), so the substrate W does not contact the first nozzle arm 26.

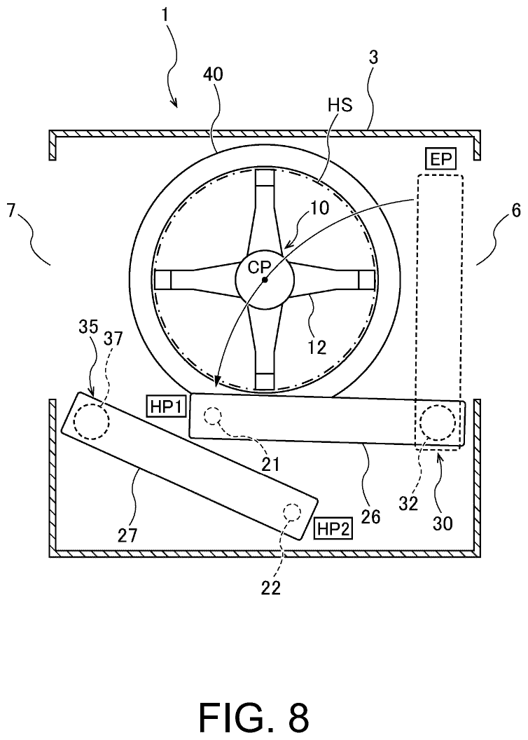

FIG. 8 is a diagram showing that the first nozzle arm 26 is moved from the retreat position EP to the first home position HP1 after the substrate W is carried out from the substrate processing module 1. In the substrate processing module 1, after the substrate W is carried out, the next substrate is carried in, and the first process and the second process are performed on the next substrate. The operation control part 50 gives a command to the first swing mechanism 30 to move the first nozzle arm 26 from the retreat position EP to the first home position HP1 after the substrate W is carried out through the carry-out port 7. As a result, when the next substrate is carried in, the first nozzle arm 26 is positioned at the first home position HP1 not on the carry-in path of the next substrate (separated from the carry-in path of the next substrate), so the next substrate does not contact the first nozzle arm 26. Similarly, when the next substrate is carried in, the second nozzle arm 27 is positioned at the second home position HP2 not on the carry-in path of the next substrate (separated from the carry-in path of the next substrate), so the next substrate does not contact the second nozzle arm 27. Moreover, by moving the first nozzle arm 26 to the first home position HP1 after the substrate W is carried out, it is possible to prevent droplets of the first fluid from falling from the first nozzle 21 and adhering to the substrate W.

According to the embodiment, the substrate processing module 1 includes the first nozzle 21 for performing the first process and the second nozzle 22 for performing the second process, so the first process and the second process can be continuously performed on the substrate W within one substrate processing module 1. As a result, space saving of the substrate processing module 1 and improvement of throughput can be achieved.

Furthermore, according to the embodiment, as described with reference to FIG. 3 to FIG. 8, by moving the first nozzle arm 26 and the second nozzle arm 27, it is possible to prevent the first nozzle arm 26 and the second nozzle arm 27 from contacting each other during the first process and the second process on the substrate W. Moreover, during carry-in and carry-out of the substrate W, it is possible to prevent the substrate W from contacting the first nozzle arm 26 and the second nozzle arm 27.

The position of the first swing shaft 32 of the first swing mechanism 30, the position of the second swing shaft 37 of the second swing mechanism 35, the first home position HP1 and the retreat position EP of the first nozzle arm 26, and the second home position HP2 of the second nozzle arm 27 shown in FIG. 3 to FIG. 8 are examples, and are not limited to this example as long as the first nozzle arm 26 and the second nozzle arm 27 do not contact each other during the first process and the second process on the substrate W, and the substrate W does not contact the first nozzle arm 26 and the second nozzle arm 27 during carry-in and carry-out of the substrate W.

In the above embodiment, the first process performed in the substrate processing module 1 is a cleaning process performed on the substrate W after polishing, and the second process is a drying process performed on the substrate W after cleaning. However, in other embodiments, the first process performed in the substrate processing module 1 may be a primary cleaning process performed on the substrate W after polishing, and the second process may be a finishing cleaning process performed on the substrate W after primary cleaning. In this case, the first nozzle 21 is a cleaning nozzle that supplies a fluid for primary cleaning used in the primary cleaning process to the substrate W, and the second nozzle 22 is a cleaning nozzle that supplies a finishing cleaning fluid used in the finishing cleaning process to the substrate W.

The first nozzle 21 for primary cleaning is configured to spray the fluid for primary cleaning toward the surface of the substrate W held and rotated by the substrate holding part 10. Examples of the fluid for primary cleaning include liquids such as chemical solutions and pure water, and two-fluid jets formed by mixed fluid of liquid (for example, chemical solutions, pure water) and gas. The second nozzle 22 for finishing cleaning is configured to spray a finishing cleaning fluid toward the surface of the substrate W held and rotated by the substrate holding part 10. Examples of the finishing cleaning fluid include liquids such as chemical solutions and pure water, and two-fluid jets formed by mixed fluid of liquid (for example, chemical solutions, pure water) and gas.

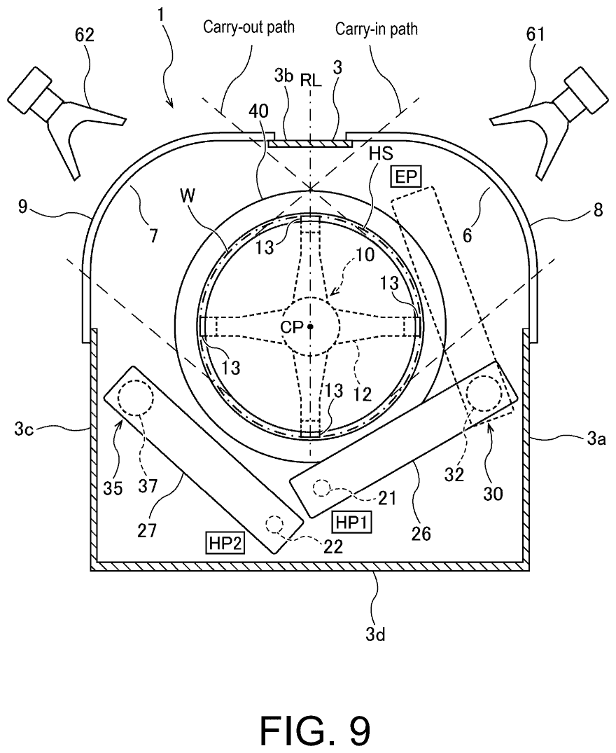

FIG. 9 is a plan view showing another embodiment of the substrate processing module 1. The configuration and the operation of the embodiment that are not specifically described are the same as the embodiment described with reference to FIG. 1 to FIG. 8, so redundant description thereof is omitted. As shown in FIG. 9, the partition wall 3 has a corner part between the sidewall 3a and the sidewall 3b, and a corner part between the sidewall 3b and the sidewall 3c that have arc shapes when viewed from the top of the substrate processing module 1.

The carry-in port 6 is formed between the sidewall 3a and the sidewall 3b of the partition wall 3, and the carry-out port 7 is formed between the sidewall 3b and the sidewall 3c of the partition wall 3. The carry-in port 6 and the carry-out port 7 are arranged symmetrically with respect to the reference line RL when viewed from the top of the substrate processing module 1. In the embodiment, the carry-in path and the carry-out path of the substrate W are inclined with respect to the reference line RL when viewed from the top of the substrate processing module 1. The first shutter 8 has an arc shape when viewed from the top of the substrate processing module 1, and is attached to close the carry-in port 6. The second shutter 9 has an arc shape when viewed from the top of the substrate processing module 1, and is attached to close the carry-out port 7.

In the embodiment as well, the first swing shaft 32 of the first swing mechanism 30 is arranged adjacent to the carry-in port 6, and the second swing shaft 37 of the second swing mechanism 35 is arranged adjacent to the carry-out port 7. The first swing mechanism 30 is configured to move the first nozzle arm 26 to the first home position HP1 and the retreat position EP. The second swing mechanism 35 is configured to move the second nozzle arm 27 to the second home position HP2.

The operation of moving the first nozzle arm 26 by the first swing mechanism 30 and the operation of moving the second nozzle arm 27 by the second swing mechanism 35 are similar to the operations described with reference to FIG. 3 to FIG. 8. Accordingly, the first nozzle arm 26 and the second nozzle arm 27 are arranged so that the first nozzle arm 26 and the second nozzle arm 27 do not contact each other during the first process and the second process on the substrate W. Also, the first nozzle arm 26 and the second nozzle arm 27 are arranged so that the substrate W does not contact the first nozzle arm 26 and the second nozzle arm 27 during carry-in and carry-out of the substrate W.

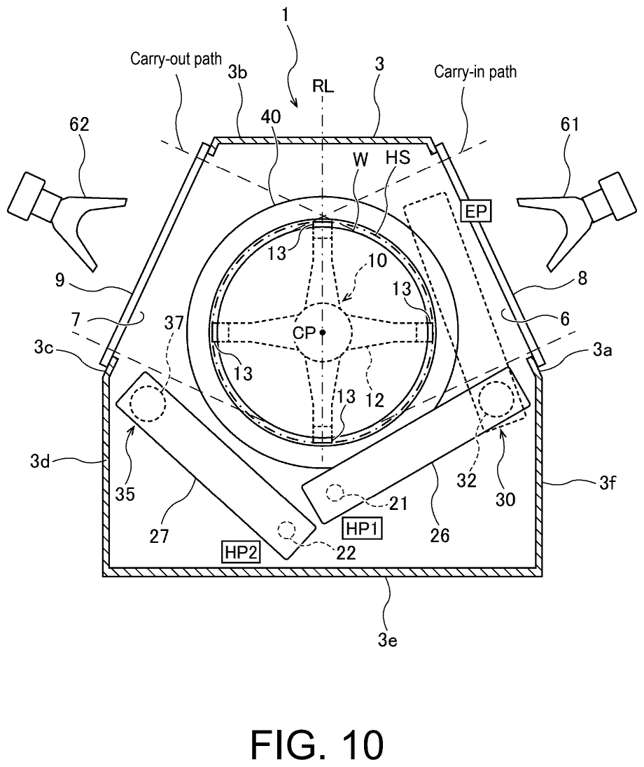

FIG. 10 is a plan view showing still another embodiment of the substrate processing module 1. The configuration and the operation of this embodiment that are not particularly described are the same as the embodiment described with reference to FIG. 1 to FIG. 8, so the overlapping description thereof is omitted. As shown in FIG. 10, the partition wall 3 has a hexagonal shape when viewed from the top of the substrate processing module 1. The partition wall 3 has six sidewalls 3a, 3b, 3c, 3d, 3e, 3f. The sidewall 3a and the sidewall 3c are inclined with respect to the reference line RL when viewed from the top of the substrate processing module 1, and are arranged symmetrically with respect to the reference line RL. The sidewall 3b and the sidewall 3e extend in parallel directions and face each other, and the sidewall 3d and the sidewall 3f extend in parallel directions and face each other. The sidewall 3a is adjacent to the sidewall 3b and the sidewall 3f, the sidewall 3c is adjacent to the sidewall 3b and the sidewall 3d, and the sidewall 3e is adjacent to the sidewall 3d and the sidewall 3f. When viewed from the top of the substrate processing module 1, the length of the sidewall 3b is smaller than the length of the sidewall 3e.

The carry-in port 6 is formed on the sidewall 3a of the partition wall 3, and the carry-out port 7 is formed on the sidewall 3c of the partition wall 3. The carry-in port 6 and the carry-out port 7 are arranged symmetrically with respect to the reference line RL when viewed from the top of the substrate processing module 1. In the embodiment, the carry-in path and the carry-out path of the substrate W are inclined with respect to the reference line RL when viewed from the top of the substrate processing module 1. The first shutter 8 is attached to the sidewall 3a of the partition wall 3 to close the carry-in port 6. The second shutter 9 is attached to the sidewall 3c of the partition wall 3 to close the carry-out port 7.

The operation of the movement of the first nozzle arm 26 by the first swing mechanism 30 and the operation of the movement of the second nozzle arm 27 by the second swing mechanism 35 are similar to the operations described with reference to FIG. 3 to FIG. 8. Accordingly, the first nozzle arm 26 and the second nozzle arm 27 are arranged so that the first nozzle arm 26 and the second nozzle arm 27 do not contact each other during the first process and the second process on the substrate W. Also, the first nozzle arm 26 and the second nozzle arm 27 are arranged so that the substrate W does not contact the first nozzle arm 26 and the second nozzle arm 27 during carry-in and carry-out of the substrate W.

The shape of the substrate processing module 1 is not limited to the above embodiment, and can be applied to a substrate processing module 1 having other shapes. In such case, the carry-in port 6 and the carry-out port 7 are arranged symmetrically with respect to a reference line RL that passes through the substrate holding surface HS of the substrate holding part 10 and extends parallel to the substrate holding surface HS when viewed from the top of the substrate processing module 1. The first swing shaft 32 is arranged adjacent to the carry-in port 6, and the second swing shaft 37 is arranged adjacent to the carry-out port 7.

The above embodiment is described for the purpose of enabling a person having ordinary knowledge in the technical field to which the disclosure belongs to implement the disclosure. Various modification examples of the above embodiment can naturally be made by those skilled in the art, and the technical concept of the disclosure can be applied to other embodiments. Therefore, the disclosure is not limited to the described embodiment, but is to be interpreted in the broadest scope according to the technical concept defined by the patent claims.

What is claimed is:

1. A substrate processing module, performing a first process and a second process after the first process on a substrate, the substrate processing module comprising:
a substrate holding part, holding the substrate;
a first nozzle, supplying a first fluid used in the first process to the substrate;
a second nozzle, supplying a second fluid used in the second process to the substrate;
a first nozzle arm, supporting the first nozzle;
a second nozzle arm, supporting the second nozzle;
a first swing mechanism, swinging the first nozzle arm in a direction parallel to a substrate holding surface of the substrate holding part;
a second swing mechanism, swinging the second nozzle arm in a direction parallel to the substrate holding surface;
a carry-in port, provided to carry the substrate into the substrate processing module; and
a carry-out port, provided to carry the substrate out of the substrate processing module,
wherein the carry-in port and the carry-out port are arranged symmetrically with respect to a reference line when viewed from top of the substrate processing module, and the reference line is a line that passes through the substrate holding surface when viewed from the top of the substrate processing module and extends parallel to the substrate holding surface,
a first swing shaft of the first swing mechanism is arranged adjacent to the carry-in port, and
a second swing shaft of the second swing mechanism is arranged adjacent to the carry-out port.

2. The substrate processing module as claimed in claim 1, wherein the first nozzle arm and the second nozzle arm are at a same height.

3. The substrate processing module as claimed in claim 1,
wherein the first swing mechanism is configured to move the first nozzle arm to a first home position and a retreat position,
the second swing mechanism is configured to move the second nozzle arm to a second home position,
the first home position is a position in which the first nozzle is arranged on an outer side of the substrate holding part and which is not on a carry-in path of the substrate,
the retreat position is a position in which the first nozzle is arranged on the outer side of the substrate holding part and the second nozzle arm is not in contact with the first nozzle arm during swinging of the second nozzle arm,
the second home position is a position in which the second nozzle is arranged on the outer side of the substrate holding part and which is not on a carry-out path of the substrate, and
the second home position is a position farther from the substrate holding part than the first home position.

4. The substrate processing module as claimed in claim 3, further comprising an operation control part controlling operations of the first swing mechanism and the second swing mechanism,
wherein the operation control part is configured to:
give a command to the first swing mechanism to swing the first nozzle arm, while supplying the first fluid from the first nozzle to the substrate, and perform the first process on the substrate,
then give a command to the first swing mechanism to move the first nozzle arm to the retreat position, and
then give a command to the second swing mechanism to swing the second nozzle arm while supplying the second fluid from the second nozzle to the substrate, and perform the second process on the substrate.

5. The substrate processing module as claimed in claim 4, wherein the operation control part is configured to, before the substrate is carried in through the carry-in port, give a command to the second swing mechanism to move the second nozzle arm to the second home position and give a command to the first swing mechanism to move the first nozzle arm to the first home position.

6. The substrate processing module as claimed in claim 4, wherein the operation control part is configured to give a command to the second swing mechanism to move the second nozzle arm to the second home position after the second process is performed on the substrate and before the substrate is carried out through the carry-out port.

7. The substrate processing module as claimed in claim 4, wherein the operation control part is configured to give a command to the first swing mechanism to move the first nozzle arm to the first home position after the substrate is carried out through the carry-out port.

8. The substrate processing module as claimed in claim 1, wherein the first process is a cleaning process and the second process is a drying process,
the first nozzle is a cleaning nozzle supplying a cleaning fluid used in the cleaning process to the substrate, and
the second nozzle is a drying nozzle supplying a drying fluid used in the drying process to the substrate.

9. The substrate processing module as claimed in claim 1, wherein the first process is a primary cleaning process and the second process is a finishing cleaning process,
the first nozzle is a cleaning nozzle for supplying a primary cleaning fluid used in the primary cleaning process to the substrate, and
the second nozzle is a cleaning nozzle for supplying a finishing cleaning fluid used in the finishing cleaning process to the substrate.

10. A substrate processing method, performing a first process and a second process after the first process on a substrate, the substrate processing method comprising:
carrying the substrate into a substrate processing module through a carry-in port;
holding the substrate by using a substrate holding part;
swinging a first nozzle arm in a direction parallel to a substrate holding surface of the substrate holding part by using a first swing mechanism while supplying a first fluid from a first nozzle supported by the first nozzle arm to the substrate to perform the first process on the substrate;
swinging a second nozzle arm in a direction parallel to the substrate holding surface by using a second swing mechanism while supplying a second fluid from a second nozzle supported by the second nozzle arm to the substrate to perform the second process on the substrate; and
carrying out the substrate from the substrate processing module through a carry-out port,
wherein the carry-in port and the carry-out port are arranged symmetrically with respect to a reference line when viewed from top of the substrate processing module, and the reference line is a line that passes through the substrate holding surface when viewed from the top of the substrate processing module and extends parallel to the substrate holding surface,
a first swing shaft of the first swing mechanism is arranged adjacent to the carry-in port, and
a second swing shaft of the second swing mechanism is arranged adjacent to the carry-out port.

11. The substrate processing method as claimed in claim 10, wherein the first nozzle arm and the second nozzle arm are at a same height.

12. The substrate processing method as claimed in claim 10, further comprising moving the first nozzle arm to a retreat position by using the first swing mechanism after the first process is performed on the substrate and before the second process is performed on the substrate,
wherein the retreat position is a position in which the first nozzle is arranged on an outer side of the substrate holding part and the second nozzle arm is not in contact with the first nozzle arm during swinging of the second nozzle arm.

13. The substrate processing method as claimed in claim 12, further comprising moving the second nozzle arm to a second home position by using the second swing mechanism and moving the first nozzle arm to a first home position by using the first swing mechanism before the substrate is carried into the substrate processing module through the carry-in port,
wherein the first home position is a position in which the first nozzle is arranged on the outer side of the substrate holding part and which is not on a carry-in path of the substrate,
the second home position is a position in which the second nozzle is arranged on the outer side of the substrate holding part and which is not on a carry-out path of the substrate, and
the second home position is a position farther from the substrate holding part than the first home position.

14. The substrate processing method as claimed in claim 12, further comprising moving the second nozzle arm to a second home position by using the second swing mechanism after the second process is performed on the substrate and before the substrate is carried out from the substrate processing module through the carry-out port,
wherein the second home position is a position in which the second nozzle is arranged on the outer side of the substrate holding part and which is not on a carry-out path of the substrate.

15. The substrate processing method as claimed in claim 12, further comprising moving the first nozzle arm to a first home position by using the first swing mechanism after the substrate is carried out from the substrate processing module through the carry-out port,
wherein the first home position is a position in which the first nozzle is arranged on the outer side of the substrate holding part and which is not on a carry-in path of the substrate.

16. The substrate processing method as claimed in claim 10, wherein the first process is a cleaning process, and the second process is a drying process,
the first nozzle is a cleaning nozzle for supplying a cleaning fluid used in the cleaning process to the substrate, and
the second nozzle is a drying nozzle for supplying a drying fluid used in the drying process to the substrate.

17. The substrate processing method as claimed in claim 10, wherein the first process is a primary cleaning process and the second process is a finishing cleaning process,
the first nozzle is a cleaning nozzle for supplying a primary cleaning fluid used in the primary cleaning process to the substrate, and
the second nozzle is a cleaning nozzle for supplying a finishing cleaning fluid used in the finishing cleaning process to the substrate.
